(19) United States
(12) Patent Application Publication
(10) Pub. No.: US 2014/0063956 A1
(43) Pub. Date: Mar. 6, 2014

(54) NONVOLATILE MEMORY DEVICE AND OPERATING METHOD THEREOF

(71) Applicant: SK HYNIX INC., Icheon-si (KR)

(72) Inventor: Sang O LIM, Icheon-si (KR)

(73) Assignee: SK HYNIX INC., Icheon-si (KR)

(21) Appl. No.: 13/779,038

(22) Filed: Feb. 27, 2013

(30) Foreign Application Priority Data
Sep. 4, 2012 (KR) 10-2012-0097798

(51) Int. Cl. G11C 16/04

(52) U.S. Cl. CPC G11C 16/04
USPC 365/185.12

(57) ABSTRACT

A nonvolatile memory device includes: a page buffer block including a plurality of cache latches configured to temporarily store data inputted to program memory cells, and configured to program the inputted data into the memory cells; and a column decoder configured to provide column select signals for selecting the cache latches to the cache latches according to a column address, wherein the column decoder activates column select signals for selecting a part of the cache latches at substantially the same time, while data are set up in the cache latches.

### CROSS-REFERENCES TO RELATED APPLICATION

The present application claims priority under 35 U.S.C. §119(a) to Korean application number 10-2012-0097798, filed on Sep. 4, 2012, in the Korean Intellectual Property Office, which is incorporated herein by reference in its entirety.

### BACKGROUND

1. Technical Field

The present invention generally relates to a semiconductor memory device, and more particularly, to a nonvolatile memory device and an operating method thereof.

2. Related Art

In general, a semiconductor memory device is classified into a volatile memory device and a nonvolatile memory device. The volatile memory device loses data stored therein when power supply is cut off, but the nonvolatile memory device maintains data stored therein even though power supply is cut off. The nonvolatile memory device may include various types of memory cells.

The nonvolatile memory device may be divided into a flash memory device, a ferroelectric RAM (FRAM) using a ferroelectric capacitor, a magnetic RAM (MRAM) using a tunneling magneto-resistive (TMR) layer, a phase change memory device using chalcogenide alloys, a resistive RAM (ReRAM) using transition metal oxide and the like, depending on the structure of memory cells.

Among the nonvolatile memory devices, the flash memory device is roughly divided into a NOR flash memory device and a NAND flash memory device, depending on the connection state between memory cells and a bit line. The NOR flash memory device has a structure in which two or more memory cell transistors are connected in parallel to one bit line. Therefore, the NOR flash memory device has an excellent random access time characteristic. On the other hand, the NAND flash memory device has a structure in which two or more memory cell transistors are connected in series to one bit line. Such a structure is referred to as a cell string, and one bit line contact is required per one cell string. Therefore, the NAND flash memory device has an excellent characteristic in terms of integration degree.

Among the nonvolatile memory devices, a flash memory device performs a program operation in a page-wise manner, due to the structural characteristic thereof. One page includes a plurality of memory cells. The memory cells forming one page are programmed by page buffer circuits corresponding to the respective memory cells. The page buffer circuits include a cache latch to temporarily store data inputted to program a memory cell. The operations of storing the inputted data in the cache latches of the respective page buffer circuits (or setting data based on a certain purpose) are sequentially performed according to column addresses. The operations of inputting data to the cache latches require a large amount of time, thereby increasing the program time of the nonvolatile memory device.

### SUMMARY

A nonvolatile memory device capable of reducing a setup time of cache latches to temporarily store input data and reducing a current required for a setup operation of the cache latches and an operating method thereof are described herein.

In an embodiment, a nonvolatile memory device includes: a page buffer block including a plurality of cache latches configured to temporarily store data inputted to program memory cells, and configured to program the inputted data into the memory cells; and a column decoder configured to provide column select signals for selecting the cache latches to the cache latches according to a column address, wherein the column decoder activates column select signals for selecting a part of the cache latches at substantially the same time, while data are set up in the cache latches.

In an embodiment, an operating method of a nonvolatile memory device includes the steps of: resetting cache latches configured to temporarily store data inputted to program memory cells; selecting a part of the reset cache latches at substantially the same time; and storing data in the selected cache latches.

### BRIEF DESCRIPTION OF THE DRAWINGS

Features, aspects, and embodiments are described in conjunction with the attached drawings, in which:

FIG. 1 is a circuit diagram for explaining a setup operation of cache latches included in a page buffer block of a nonvolatile memory device according to an embodiment;

FIG. 2 is a timing diagram for explaining the setup operation of the cache latches of FIG. 1;

FIG. 3 is a circuit for explaining a masking operation for a cache latch corresponding to a fail column according to an embodiment;

FIG. 4 is a timing diagram for explaining the masking operation for the cache latch corresponding to the fail column of FIG. 3;

FIG. 5 is a block diagram illustrating the nonvolatile memory device according to an embodiment;

FIG. 6 is a block diagram illustrating a data processing system including the nonvolatile memory device according to an embodiment;

FIG. 7 illustrates a memory card including the nonvolatile memory device according to an embodiment;

FIG. 8 is a block diagram illustrating the internal configuration of the memory card of FIG. 7 and the connection relation between the memory card and a host;

FIG. 9 is a block diagram illustrating an SSD including the nonvolatile memory device according to an embodiment;

FIG. 10 is a block diagram illustrating an SSD controller of FIG. 9; and

FIG. 11 is a block diagram illustrating a computer system in which a data storage device including the nonvolatile memory device according to an embodiment is mounted.

### DETAILED DESCRIPTION

Hereinafter, a nonvolatile memory device and an operating method thereof according to various embodiments will be described below with reference to the accompanying drawings through the embodiments.

Various embodiments will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of these embodiments to those skilled in the art.

The drawings are not necessarily to scale and in some instances, proportions may have been exaggerated in order to clearly illustrate features of the embodiments. In this specification, specific terms have been used. The terms are used to describe the various embodiments, and are not used to qualify the sense or limit the scope of the embodiments.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include a plural form as long as it is not specifically mentioned in a sentence. Furthermore, ‘include/comprise’ or ‘including/comprising’ used in the specification represents that one or more components, steps, operations, and elements exists or are added.

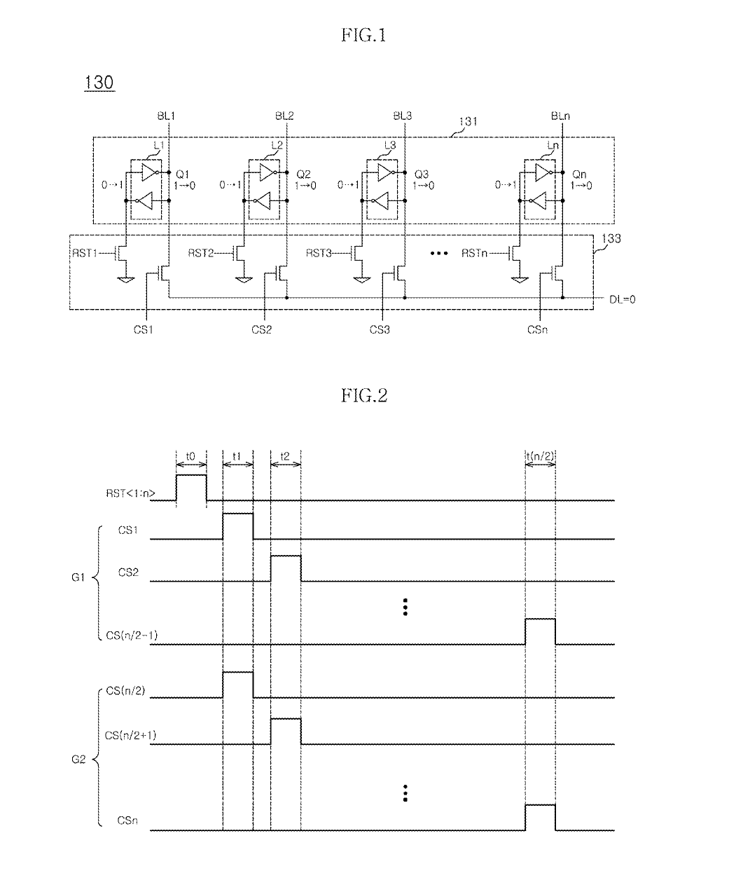

FIG. 1 is a circuit diagram for explaining a setup operation of cache latches included in a page buffer block of a nonvolatile memory device according to an embodiment. FIG. 2 is a timing diagram for explaining the setup operation of the cache latches of FIG. 1. Hereafter, referring to FIGS. 1 and 2, an operation of setting the same data in the cache latches included in the page buffer block of the nonvolatile memory device will be described in detail.

Referring to FIG. 1, the page buffer block 130 of the nonvolatile memory device may include a cache latch block 131 and control circuits 133 for setting up the cache latch block 131. The cache latch block 131 may include a plurality of cache latches L1 to Ln corresponding to bit lines BL1 to BLn, respectively. Each of the cache latches L1 to Ln may be configured to temporarily store data inputted from the outside according to a column address. That is, each of the cache latches L1 to Ln may be configured to temporarily store data inputted to program a program cell connected to a corresponding bit line BL.

The operation of setting up the data inputted to the cache latches L1 to Ln may include an operation of collectively resetting the cache latches L1 to Ln and an operation of selecting a part of the cache latches L1 to Ln and storing data in the selected cache latches. According to an embodiment, when the same data are set up in the cache latches L1 to Ln, the operations of storing data in the cache latches selected by selecting a part of the cache latches L1 to Ln at substantially the same time may be performed in parallel. This means that the time required for setting up the cache latches may be reduced.

In order to select a part of the cache latches L1 to Ln at the same time or substantially the same time, the cache latches L1 to Ln are divided into two or more groups, and one or more cache latches may be simultaneously selected for each group. For convenience of description, FIG. 2 illustrates that the cache latches L1 to Ln are divided into two groups G1 and G2 and one cache latch is selected per group. For example, the cache latch selected from the first group G1 and the cache latch selected from the second group G2 may be simultaneously enabled or substantially simultaneously enabled to set up the same data.

A cache latch may be selected when a column select signal CS is activated (i.e., CS1 to CSn). The column select signal CS is activated to select a bit line and a circuit block corresponding to the bit line, and may be generated as a decoding result of a column address. During the decoding operation for the column address, column select signals CS may be activated to select a cache latch included in the first group G1 and a cache latch included in the second group G2 at the same time or substantially the same time.

Before data are stored in the cache latches L1 to Ln, the cache latches L1 to Ln are collectively reset. For example, during a time t0, when cache latch reset signals RST1 to RSTn are simultaneously activated or substantially simultaneously activated, values of specific nodes Q1 to Qn of the cache latches L1 to Ln are set to an initial value (for example, data ‘1’ or logic high value).

After the cache latches L1 to Ln are reset, one or more cache latches are simultaneously selected or substantially simultaneously selected for each group. For example, during a time t1, a column select signal CS1 for selecting a cache latch L1 of the first group G1 and a column select signal CS(n/2) for selecting a cache latch L(n/2) of the second group G2 are simultaneously activated or substantially simultaneously activated. Specific nodes Q1 and Q(n/2) of the selected cache latches L1 and L(n/2) are simultaneously set or substantially simultaneously set to a value applied to a data line DL (for example, data ‘0’ or logic low value).

Additionally, the physical order (or position) of the selected cache latch L1 within the first group G1 may be equal to the physical order (or position) of the selected cache latch L(n/2) within the second group G2. For example, although not illustrated, the physical order of the cache latch L1 within the first group G1 may correspond to the first, and the physical order of the cache latch L(n/2) within the second group G2 may also correspond to the first.

During a time t2, a column select signal CS2 for selecting a cache latch L2 of the first group G1 and a column select signal CS(n/2+1) for selecting a cache latch L(n/2+1) of the second group G2 are simultaneously activated or substantially simultaneously activated. Specific nodes Q2 and Q(n/2+1) of the selected cache latches L2 and L(n/2+1) are simultaneously set or substantially simultaneously set to the value applied to the data line DL (for example, data ‘0’ or logic low value).

Additionally, the physical order (or position) of the selected cache latch L2 within the first group G1 may be equal to the physical order (or position) of the selected cache latch L(n/2+1) within the second group G2. For example, although not illustrated, the physical order of the cache latch L2 within the first group G1 may correspond to the second, and the physical order of the cache latch L(n/2+1) within the second group G2 may also correspond to the second.

In this way, the other cache latches are set to the same data value applied to the data line. Additionally, FIG. 2 also illustrates a time at time t(n/2).

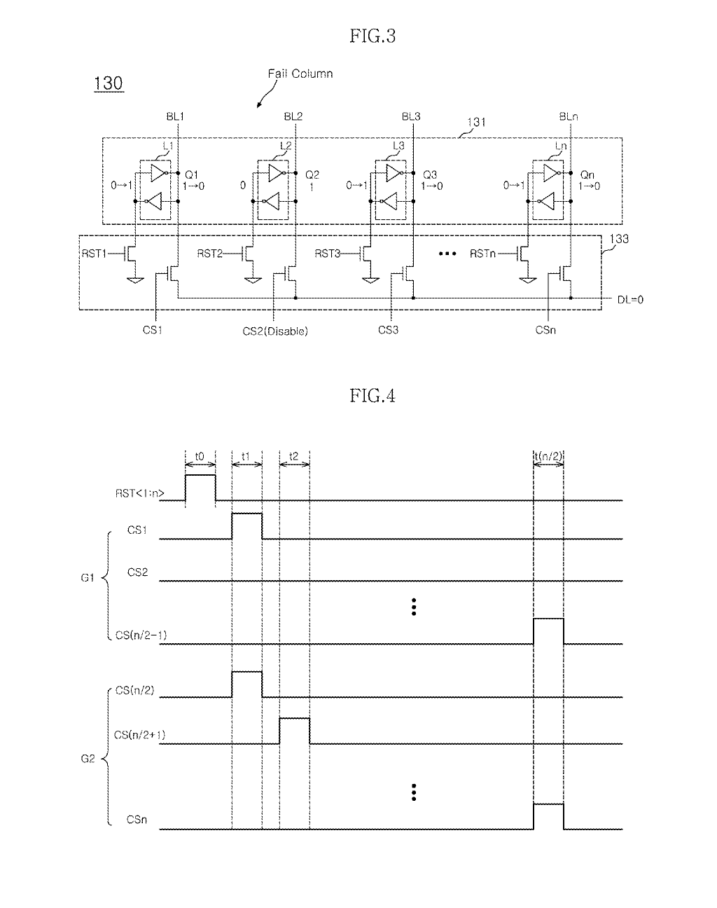

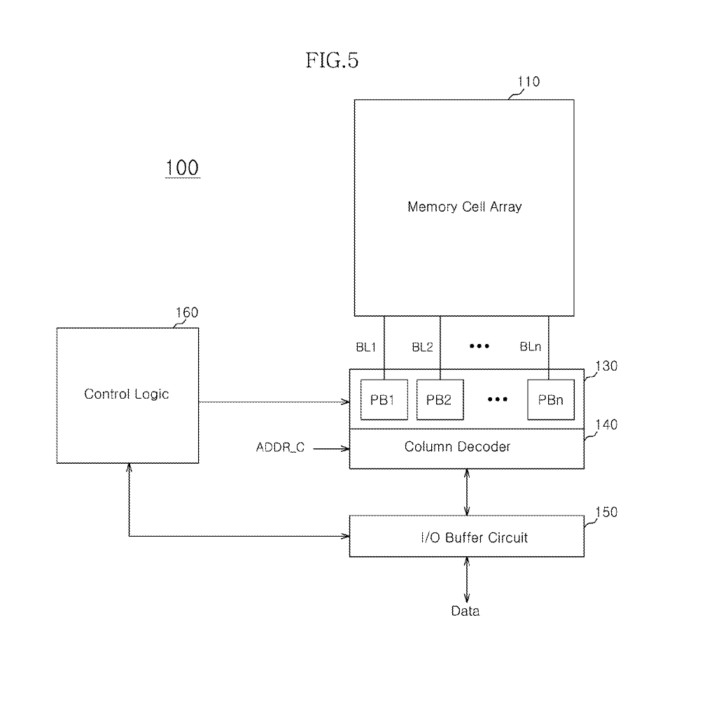

FIG. 3 is a circuit for explaining a masking operation for a cache latch corresponding to a fail column according to an embodiment. FIG. 4 is a timing diagram for explaining the masking operation for the cache latch corresponding to the fail column of FIG. 3. Hereafter, referring to FIGS. 3 and 4, an operation of masking a cache latch corresponding to a fail column will be described in detail.

FIG. 3 briefly illustrates a cache latch block 131 included in a page buffer block 130 of the nonvolatile memory device and control circuits 133 for setting up the cache latch block 131. The cache latch block 131 may include a plurality of cache latches L1 to Ln corresponding to bit lines BL1 to BLn, respectively. Each of the cache latches L1 to Ln may be configured to temporarily store data inputted according to a column address. That is, each of the cache latches L1 to Ln may be configured to temporarily store data inputted to program a memory cell connected to a corresponding bit line BL.

In order to perform a masking operation for a fail column, fail column data may be stored in a cache latch corresponding to the fail column. Such an operation is defined as a redundancy data-in operation. Referring to FIG. 4, the value of a specific node Q2 of the cache latch L2 corresponding to the fail column, that is, the bit line BL2 is set to the fail column data (for example, data ‘1’ or logic high value) by the redundancy data-in operation. Furthermore, the values of specific nodes Q1 and Q3 to Qn of the cache latches L1 and L3 to Ln corresponding to normal bit lines BL1 and BL3 to BLn are set to a value applied to the data line DL (for example, data ‘0’ or logic low value). When the fail column data is stored in the cache latch corresponding to the fail column by the redundancy data-in operation, a memory cell connected to the fail column does not have an effect on a pass/fail effect of a program or erase operation.

The operation of masking the cache latch corresponding to the fail column may include an operation of collectively resetting the cache latches L1 to Ln and an operation of selecting the cache latches L1 and L3 to Ln excluding the cache latch L2 corresponding to the fail column and storing data applied to the data line DL in the selected cache latches. Through such an operation, the fail column data is stored only in the cache latch L2 corresponding to the fail column, and the same data are stored in the other cache latches L1 and L3 to Ln. According to an embodiment, when the same data are set up in the other cache latches L1 to L3 to Ln excluding the cache latch L2 corresponding to the fail column, operations of storing in the cache latches selected by selecting a part of the cache latches L1 and L3 to Ln at the same time may be performed in parallel. This means that the time required for the redundancy data-in operation may be reduced.

In order to select a part of the cache latches L1 to Ln at the same time or substantially the same time, the cache latches L1 to Ln are divided into two or more groups, and one or more cache latches are simultaneously selected or substantially simultaneously selected for each group. For convenience of description, FIG. 4 illustrates that the cache latches L1 to Ln are divided into two groups G1 and G2, and one cache latch is selected per group. For example, a cache latch selected within the first group G1 and a cache latch selected within the second group G2 are simultaneously enabled or substantially simultaneously enabled to set up the same data.

A cache latch is selected when a column select signal CS is activated. The column select signal CS is activated to select a bit line and a circuit block corresponding to the bit line, and may be generated as a decoding result of a column address. During the decoding operation for the column address, column select signals CS may be activated to select a cache latch included in the first group G1 and a cache latch included in the second group G2 at the same time or substantially the same time. During the decoding operation for the column address, a fail column address is replaced with an address of a redundancy column for replacing a fail column. Therefore, a column select signal for selecting a cache latch corresponding to the fail column is not activated.

Before data are stored in the cache latches L1 to Ln, the cache latches L1 to Ln are collectively reset. For example, during a time t0, when cache latch reset signals RST1 to RSTn are simultaneously activated or substantially simultaneously activated, the values of specific values Q1 to Qn of the cache latches L1 to Ln are set to an initial value (that is, data ‘1’ or logic high value).

After the cache latches L1 to Ln are reset, one or more cache latches are simultaneously selected or substantially simultaneously selected for each group. For example, during a time t1, a column select signal CS1 for selecting a cache latch L1 of the first group G1 and a column select signal CS2 for selecting a cache latch L(n/2) of the second group G2 are activated. Specific nodes Q1 and Q(n/2) of the selected cache latches L1 and L(n/2) are set to a value applied to the data line DL (that is, data ‘0’ or logic low value). In this way, the other cache latches are set to the same data value applied to the data line.

As described above, when a fail column exists, a cache latch corresponding to the fail column is set to a different data value from normal cache latches (that is, fail column data). In this case, a cache latch is not selected from a group including the fail column. Referring to FIG. 4, during a time t2, only a column select signal CS(n/2+1) for selecting a cache latch L(n/2+1) of the second group G2 is activated, and a column select signal CS2 for selecting a cache latch L2 corresponding to the fail column is not activated. Therefore, the specific node Q2 of the cache latch L2 corresponding to the fail column may maintain the initial value, that is, the fail column data.

FIG. 5 is a block diagram illustrating the nonvolatile memory device according to an embodiment. Referring to FIG. 5, the nonvolatile memory device 100 may include a memory cell 110, a page buffer block 130, a column decoder 140, an input/output (I/O) buffer circuit 150, and a control logic 160.

The memory cell array 110 may include a plurality of memory cells arranged at the respective intersections between bit lines BL1 to BLn and word lines (not illustrated). The memory cells are programmed in a page-wise manner and erased in a block-wise manner, due to the structural characteristic thereof. The page indicates a unit for grouping memory cells to perform a program or read operation. The block indicates a unit for grouping memory cells to perform an erase operation. One memory block may include a plurality of pages.

The page buffer block 130 is operated according to the control of the control logic 160. The page buffer block 130 may be configured to operate as a write driver or sense amplifier depending on the operation mode. For example, the page buffer block 130 may be configured to store data inputted through the I/O buffer circuit 150 in memory cells of the memory cell array 110 during a program operation. For this operation, the page buffer block 130 may include a cache latch block (refer to FIG. 1 or 3) configured to temporarily store input data. As another example, the page buffer block 130 may be configured to output data read from memory cells of the memory cell array 110 to the I/O buffer circuit 150 during a read operation.

The page buffer block 130 may include a plurality of page buffers PB1 to PBn corresponding to a plurality of bit lines BL1 to BLn (or bit line pairs), respectively. For this reason, the bit lines BL1 to BLn (or bit line pairs) may be selected or controlled by the corresponding page buffers PB1 to PBn.

The column decoder 140 may be configured to decode a column address ADDR_C. The column decoder 140 may be configured to select the page buffers PB1 to PBn of the page buffer block 130 according to the decoding result. As described above, the column decoder 140 may be configured to activate column select signals CS to select a cache latch of a page buffer included in the first group and a cache latch of a page buffer included in the second group at the same time, during the decoding operation for the column address ADDR_C.

The I/O buffer circuit 150 may be configured to receive data from an external device (for example, a memory controller, a memory interface, a host device or the like) or output data to the external device. For this operation, the I/O buffer circuit 150 may include a data latch circuit (not illustrated) and an output driving circuit (not illustrated).

The control logic 160 may be configured to control overall operations of the nonvolatile memory device 100 in response to control signals provided from the external device. For example, the control logic 160 may control read, program (or write), and erase operations of the nonvolatile memory device 100.

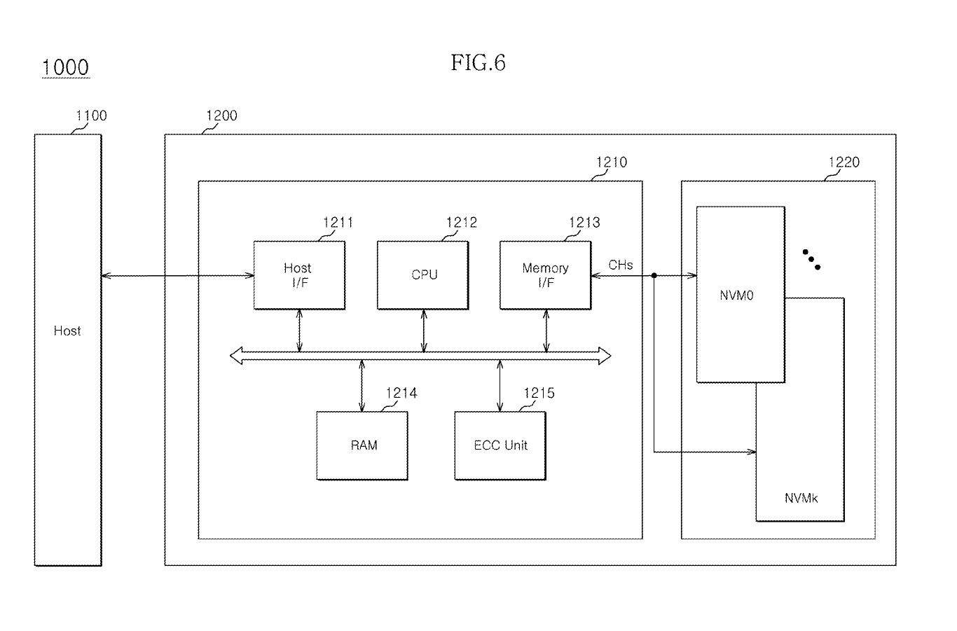

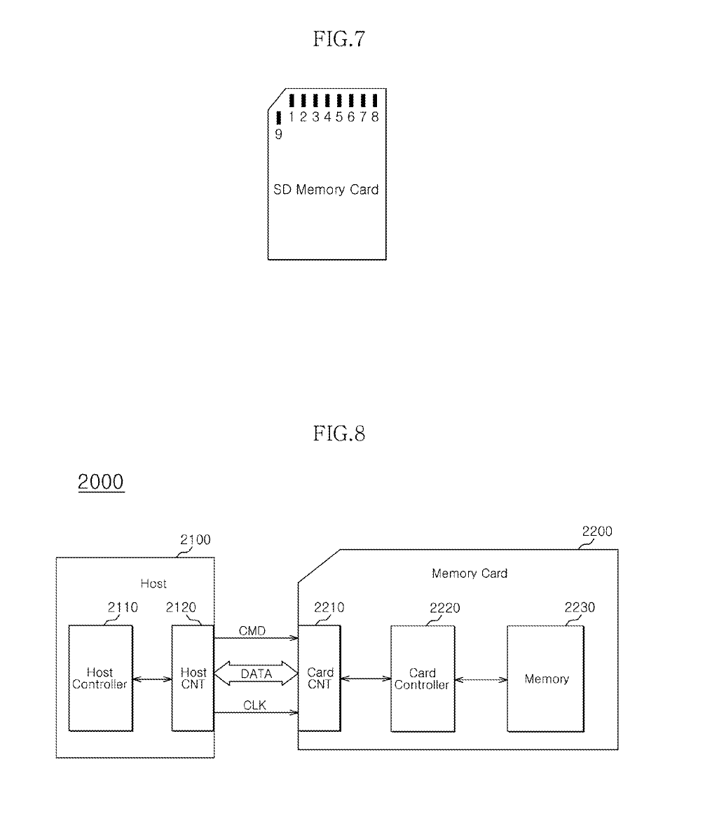

FIG. 6 is a block diagram illustrating a data processing system including the nonvolatile memory device according to an embodiment. Referring to FIG. 6, the data processing system 1000 may include a host 1100 and a data storage device 1200. The data storage device 1200 may include a controller 1210 and a data storage medium 1220. The data storage device 1200 may be connected to the host 1100 such as a desktop computer, a notebook computer, a digital camera, a mobile phone, an MP3 player, a game machine or the like. The data storage device 1200 is also referred to as a memory system.

The controller 1210 is coupled to the host 1100 and the data storage medium 1220. The controller 1210 may be configured to access the data storage medium 1220 in response to a request from the host 1100. For example, the controller 1210 may be configured to control a read, program, or erase operation of the data storage medium 1220. The controller 1210 may be configured to drive firmware for controlling the data storage medium 1220.

The controller 1210 may include well-known components such as a host interface 1211, a central processing unit (CPU) 1212, a memory interface 1213, a RAM 1214, and an error correction code (ECC) unit 1215.

The CPU 1212 may be configured to control overall operations of the controller 1210 in response to a request of the host. The RAM 1214 may be used as a working memory of the CPU 1212. The RAM 1214 may temporarily store data read from the data storage medium 1220 or data provided from the host 1100.

The host interface 1211 may be configured to interface the host 1100 and the controller 1210. For example, the host interface 1211 may be configured to communicate with the host 1100 through one of various protocols of a USB (Universal Serial Bus) protocol, a MMC (Multimedia Card) protocol, a PCI (Peripheral Component Interconnection) protocol, a PCI-E (PCI-Express) protocol, a PATA (Parallel Advanced Technology Attachment) protocol, a SATA (Serial ATA) protocol, a SCSI (Small Computer System Interface) protocol, a SAS (Serial SCSI), and an IDE (Integrated Drive Electronics) protocol.

The memory interface 1213 may be configured to interface the controller 1210 and the data storage medium 1220. The memory interface 1213 may be configured to provide a command and address to the data storage medium 1220. Furthermore, the memory interface 1213 may be configured to exchange data with the data storage medium 1220.

The data storage medium 1220 may be configured with the nonvolatile memory device 100 of FIG. 1 according to an embodiment. The data storage medium 1220 may include a plurality of nonvolatile memory devices NVMO to NVMk. As the data storage medium 1220 may be configured with the nonvolatile memory device 100 according to an embodiment, the operating speed of the data storage device 1200 may be increased, and the power consumption of the data storage device 1200 may be reduced.

The ECC unit 1215 may be configured to detect an error of the data read from the data storage medium 1220. Furthermore, the ECC unit 1215 may be configured to correct the detected error, when the detected error falls within a correction range. Meanwhile, the ECC unit 1215 may be provided inside or outside the controller 1210 depending on the memory system 1000.

The controller 1210 and the data storage medium 1220 may be configured as a solid state drive (SSD).

As another example, the controller 1210 and the data storage medium 1220 may be integrated into one semiconductor device to form a memory card. For example, the controller 1210 and the data storage medium 1220 may be integrated into one semiconductor device to form a PCMCIA (personal computer memory card international association) card, a CF (compact flash) card, a smart media card, a memory stick, a multi-media card (MMC, RS-MMC, or MMC-micro), an SD (secure digital) card (SD, Mini-SD, or Micro-SD), or a UFS (universal flash storage) card.

As another example, the controller 1210 or the data storage medium 1220 may be mounted as various types of packages. For example, the controller 1210 or the data storage medium 1220 may be packaged and mounted according to various methods such as POP (package on package), ball grid arrays (BGAs), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat package (MQFP), thin quad flat package (TQFP), small outline IC (SOIC), shrink small outline package (SSOP), thin small outline package (TSOP), thin quad flat package (TQFP), system in package (SIP), multi chip package (MCP), wafer-level fabricated package (WFP), and wafer-level processed stack package (WSP).

FIG. 7 illustrates a memory card including the nonvolatile memory device according to an embodiment. FIG. 7 illustrates the exterior of an SD (secure digital) card among memory cards.

Referring to FIG. 7, the SD card may include one command pin (for example, second pin), one clock pin (for example, fifth pin), four data pins (for example, first, seventh, eighth, and ninth pins), and three power supply pins (for example, third, fourth, and sixth pins).

Through the command pin (second pin), a command and a response signal are transferred. In general, the command is transmitted to the SD card from a host, and the response signal is transmitted to the host from the SD card.

The data pins (first, seventh, eighth, and ninth pins) are divided into receive (Rx) pins for receiving data transmitted from the host and transmit (Tx) pins for transmitting data to the host. The Rx pins and the Tx pins, respectively, form a pair to transmit differential signals.

The SD card may include the nonvolatile memory device 100 of FIG. 1 according to an embodiment and a controller for controlling the nonvolatile memory device. The controller included in the SD card may have the same configuration and function as the controller 1210 described with reference to FIG. 6.

FIG. 8 is a block diagram illustrating the internal configuration of the memory card of FIG. 7 and the connection is relation between the memory card and a host. Referring to FIG. 8, the data processing system 2000 may include a host 2100 and a memory card 2200. The host 2100 may include a host controller 2110 and a host connection unit 2120. The memory card 2200 may include a card connection unit 2210, a card controller 2220, and a memory device 2230.

The host connection unit 2120 and the card connection unit 2210 include a plurality of pins. The pins may include a command pin, a clock pin, a data pin, and a power supply pin. The number of pins may differ depending on the type of the memory card 2200.

The host 2100 stores data in the memory card 2200 or reads data stored in the memory card 2200.

The host controller 2110 transmits a write command CMD, a clock signal CLK generated from a clock generator (not illustrated) inside the host 2100, and data DATA to the memory card 2200 through the host connection unit 2120. The card controller 2220 operates in response to the write command received through the card connection unit 2210. The card controller 2220 stores the received data DATA in the memory device 2230, using a clock signal generated from a clock generator (not illustrated) inside the card controller 2220, according to the received clock signal CLK.

The host controller 2110 transmits a read command CMD and the clock signal CLK generated from the clock generator inside the host device 2100 to the memory card 2200 through the host connection unit 2120. The card controller 2220 operates in response to the read command received through the card connection unit 2210. The card controller 2220 reads data from the memory device 2230 using the clock signal generated from the clock generator inside the card controller 2220, according to the received clock signal CLK, and transmits the read data to the host controller 2110.

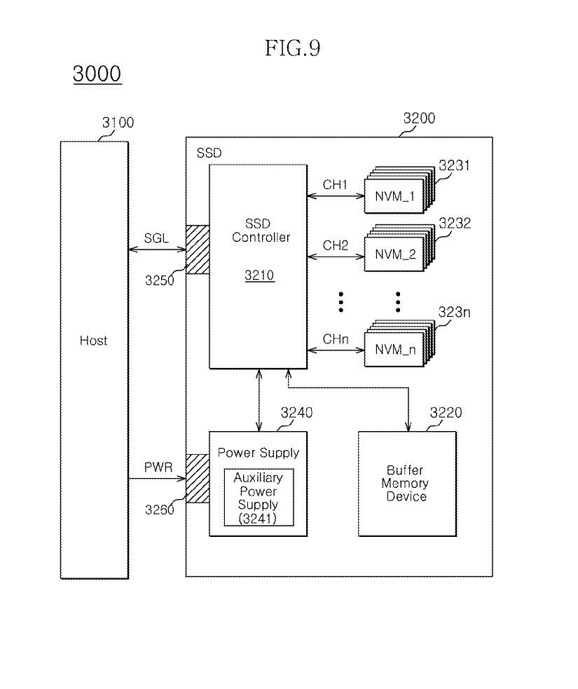

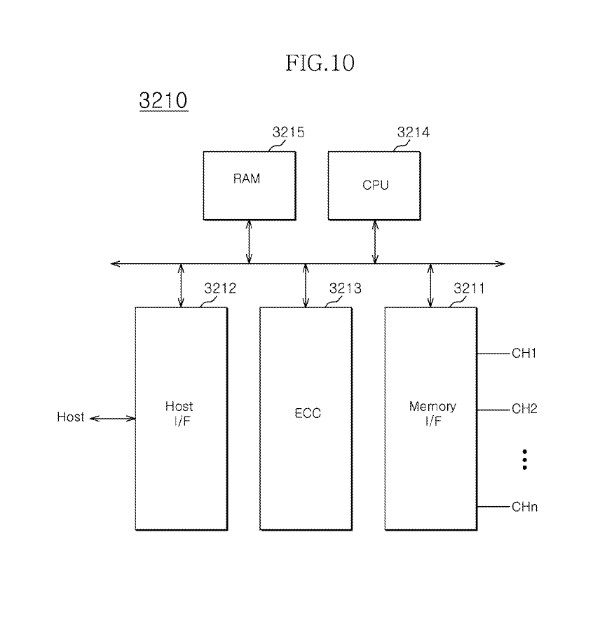

FIG. 9 is a block diagram illustrating an SSD including the nonvolatile memory device according to an embodiment. Referring to FIG. 9, a data processing system 3000 may include a host 3100 and an SSD 3200.

The SSD 3200 may include an SSD controller 3210, a buffer memory device 3220, a plurality of nonvolatile memory devices 3231 to 323n, a power supply 3240, a signal connector 3250, and a power connector 3260.

The SSD 3200 operates in response to a request of the host device 3100. That is, the SSD controller 3210 may be configured to access the nonvolatile memory devices 3231 to 323n in response to a request from the host 3100. For example, the SSD controller 3210 may be configured to control read, program, and erase operations of the nonvolatile memory devices 3231 to 323n.

The buffer memory device 3220 may be configured to temporarily store data which are to be stored in the nonvolatile memory devices 3231 to 323n. Furthermore, the buffer memory device 3220 may be configured to temporarily store data read from the nonvolatile memory devices 3231 to 323n. The data temporarily stored in the buffer memory device 3220 are transmitted to the host 3100 or the nonvolatile memory devices 3231 to 323n, according to the control of the SSD controller 3210.

The nonvolatile memory devices 3231 to 323n are used as storage media of the SSD 3200. Each of the nonvolatile memory devices 3231 to 323n may include the nonvolatile memory device 100 of FIG. 5 according to an embodiment. Therefore, the operating speed of the SSD 3200 may be increased, and the current consumption of the SSD 3200 may be reduced.

The respective nonvolatile memory devices 3231 to 323n are connected to the SSD controller 3210 through a plurality of channels CH1 to CHn. One channel may be connected to one or more nonvolatile memory devices. The nonvolatile memory devices connected to one channel may be connected to the same signal bus and data bus.

The power supply 3240 may be configured to provide power PWR inputted through the power connector 3260 into the SSD 3200. The power supply 3240 may include an auxiliary power supply 3241. The auxiliary power supply 3241 may be configured to supply power to normally terminate the SSD 3200, when sudden power off occurs. The auxiliary power supply 3241 may include super capacitors capable of storing the power PWR.

The SSD controller 3210 may be configured to exchange signals SGL with the host 3100 through the signal connector 3250. Here, the signals SGL may include commands, addresses, data and the like. The signal connector 3250 may include a connector such as PATA (Parallel Advanced Technology Attachment), SATA (Serial Advanced Technology Attachment), SCSI (Small Computer System Interface), or SAS (Serial SCSI), according to the interface method between the host 3100 and the SSD 3200.

FIG. 10 is a block diagram illustrating the SSD controller of FIG. 9. Referring to FIG. 10, the SSD controller 3210 may include a memory interface 3211, a host interface 3212, an ECC unit 3213, a CPU 3214, and a RAM 3215.

The memory interface 3211 may be configured to provide a command and address to the nonvolatile memory devices 3231 to 323n. Furthermore, the memory interface 3211 may be configured to exchange data with the nonvolatile memory devices 3231 to 323n. The memory interface 3211 may scatter data transferred from the buffer memory device 3220 over the respective channels CH1 to CHn, according to the control of the CPU 3214. Furthermore, the memory interface 3211 transmits data read from the nonvolatile memory devices 3231 to 323n to the buffer memory device 3220, according to the control of the CPU 3214.

The host interface 3212 may be configured to provide an interface with the SSD 3200 in response to the protocol of the host 3100. For example, the host interface 3212 may be configured to communicate with the host 3100 through one of PATA (Parallel Advanced Technology Attachment), SATA (Serial Advanced Technology Attachment), SCSI (Small Computer System Interface), SAS (Serial SCSI) protocols. Furthermore, the host interface 3212 may perform a disk emulation function of supporting the host 3100 to recognize the SSD 3200 as a hard disk drive (HDD).

The ECC unit 3213 may be configured to generate parity bits based on the data transmitted to the nonvolatile memory devices 3231 to 323n. The generated parity bits may be stored in spare areas of the nonvolatile memory devices 3231 to 323n. The ECC unit 3213 may be configured to detect an error of data read from the nonvolatile memory devices 3231 to 323n. When the detected error falls within a correction range, the ECC unit 3213 may correct the detected error.

The CPU 3214 may be configured to analyze and process a signal SGL inputted from the host 3100. The CPU 3214 controls overall operations of the SSD controller 3210 in response to a request of the host 3100. The CPU 3214 controls the operations of the buffer memory device 3220 and the nonvolatile memory devices 3231 to 323n according to firmware for driving the SSD 3200. The RAM 3215 is used as a working memory device for driving the firmware.

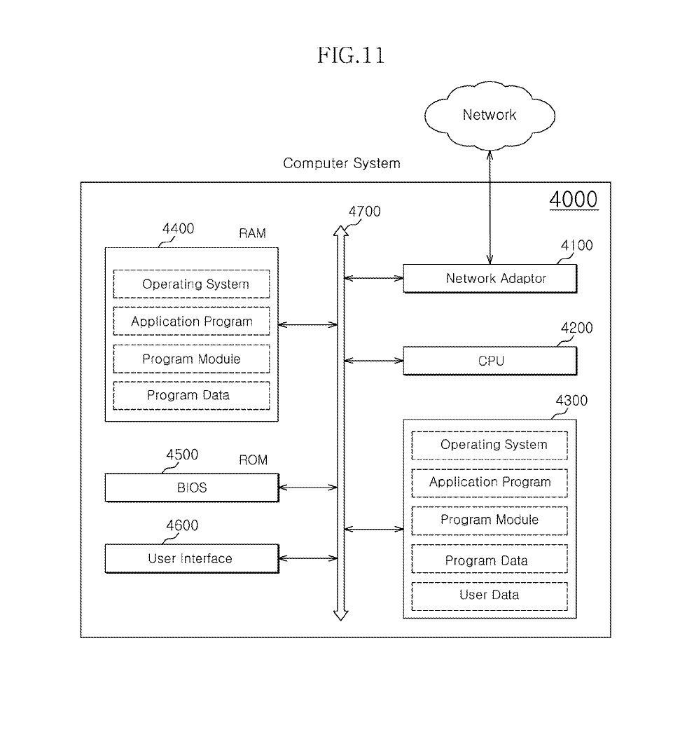

FIG. 11 is a block diagram illustrating a computer system in which a data storage device including the nonvolatile memory device according to an embodiment is mounted. Referring to FIG. 11, the computer system 4000 may include a network adapter 4100, a CPU 4200, a data storage device 4300, a RAM 4400, a ROM 4500, and a user interface 4600, which are electrically connected to the system bus 4700. Here, the data storage device 4300 may include the data storage device 1200 illustrated in FIG. 6 or the SSD 3200 illustrated in FIG. 9.

The network adapter 4100 may be configured to provide an interface between the computer system 4000 and external networks. The CPU 4200 may be configured to perform overall arithmetic operations for driving an operating system or application programs staying in the RAM 4400.

The data storage device 4300 may be configured to store overall data required by the computer system 4000. For example, the operating system for driving the computer system 4000, application programs, various program modules, program data, and user data may be stored in the data storage device 4300.

The RAM 4400 may be used as a working memory device of the computer system 4000. During booting, the operating system, application programs, various program modules, which are read from the data storage device 4300, and program data required for driving the programs are loaded into the RAM 4400. The ROM 4500 stores a basic input/output system (BIOS) which is enabled before the operating system is driven. Through the user interface 4600, information exchange is performed between the computer system 4000 and a user.

Although not illustrated in the drawing, the computer system 4000 may further include a battery, application chipsets, a camera image processor (CIP) and the like.

According to the embodiments, it is possible to reduce the current or time required for the program operation of the nonvolatile memory device.

While various embodiments have been described above, it will be understood to those skilled in the art that the embodiments described are by way of example only. Accordingly, the nonvolatile memory device described herein should not be limited based on the described embodiments.

What is claimed is:

1. A nonvolatile memory device comprising:
a page buffer block comprising a plurality of cache latches configured to temporarily store data inputted to program memory cells, and configured to program the inputted data into the memory cells; and
a column decoder configured to provide column select signals for selecting the cache latches to the cache latches according to a column address,
wherein the column decoder activates column select signals for selecting a part of the cache latches at substantially the same time, while data are set up in the cache latches.

2. The nonvolatile memory device according to claim 1, wherein the cache latches are divided into first and second cache latch groups, and
the column decoder activates column select signals to select one or more cache latches for each of the first and second cache latch groups at substantially the same time.

3. The nonvolatile memory device according to claim 2, wherein the cache latch selected from the first cache latch group and the cache latch selected from the second cache latch group have the same physical order within the respective groups.

4. The nonvolatile memory device according to claim 2, wherein the column decoder deactivates a column select signal so as not to select a cache latch corresponding to a fail column among the cache latches included in the first and second cache latch groups.

5. The nonvolatile memory device according to claim 1, wherein the data set up in the respective latch latches are equal to each other.

6. An operating method of a nonvolatile memory device, comprising the steps of:
resetting cache latches configured to temporarily store data inputted to program memory cells;
is selecting a part of the reset cache latches at substantially the same time; and
storing data in the selected cache latches.

7. The operating method according to claim 6, wherein the step of selecting a part of the reset cache latches comprises the step of dividing the cache latches into two or more of groups.

8. The nonvolatile memory device according to claim 7, wherein the step of selecting a part of the reset cache latches comprises the step of selecting one or more cache latches for each of the groups at substantially the same time.

9. The nonvolatile memory device according to claim 8, wherein the step of selecting a part of the reset cache latches comprises the step of selecting cache latches whose physical orders are equal to each other within the respective groups.

10. The nonvolatile memory device according to claim 8, wherein, in the step of selecting one or more cache latches for each of the groups,
when a cache latch corresponding to a fail column is a select target, the cache latch corresponding to the fail column is not selected.

11. The nonvolatile memory device according to claim 10, wherein the step of storing the data in the selected cache latches comprises the step of storing the same data in the selected cache latches.

12. The nonvolatile memory device according to claim 10, wherein the cache latch corresponding to the fail column maintains reset data.

13. The nonvolatile memory device according to claim 12, wherein the cache latch corresponding to the fail column does not have an effect on a pass/fail determination operation due to the reset data.
